(19) United States
(12) Patent Application Publication
(10) Pub. No.: US 2017/0012166 A1
(43) Pub. Date: Jan. 12, 2017

(54) SEMICONDUCTOR LIGHT-EMITTING ELEMENT

(71) Applicant: Ushio Denki Kabushiki Kaisha, Tokyo (JP)

(72) Inventor: Kohei MIYOSHI, Himeji-shi (JP)

(73) Assignee: USHIO DENKI KABUSHIKI KAISHA, Tokyo (JP)

(21) Appl. No.: 15/116,268

(22) PCT Filed: Feb. 2, 2015
(86) PCT No.: PCT/JP2015/052791

§ 371 Date: Aug. 3, 2016

(30) Foreign Application Priority Data
Feb. 5, 2014 (JP) 2014-020387

(51) Int. Cl. H01L 33/04; H01L 33/32

(52) U.S. Cl. CPC H01L 33/04; H01L 33/32

(57) ABSTRACT

Provided is a semiconductor light emitting element formed by growing an active layer in the c-axis direction and having a peak emission wavelength of at least 530 nm, wherein the light emission efficiency is greater than the conventional art. A semiconductor light-emitting element has a peak emission wavelength of greater than or equal to 530 nm, and comprise: an n-type semiconductor layer; an active layer formed above n-type semiconductor layer; and a p-type semiconductor layer formed above the active layer. In the active layer, a first layer composed of In_{X1}Ga_{1-X1}N (0≦X1≦0.01), a second layer composed of In_{X2}Ga_{1-X2}N (0.2<X2<1), and a third layer composed of Al_{Y1}Ga_{1-Y1}N (0<Y1<1) are laminated, and at least the first layer and the second layer are formed cyclically.

### TECHNICAL FIELD

The present invention relates to a semiconductor light-emitting element, in particular, a semiconductor light-emitting element showing a peak emission wavelength of greater than or equal to 530 nm. The present invention also relates to a method for producing such a semiconductor light-emitting element.

### BACKGROUND ART

In recent years, development of projectors and medical examination devices using a LED having an emission wavelength in the visible light range has been advanced. As a LED having an emission wavelength in the visible light range, conventionally, a GaP compound semiconductor is mainly used. However, the GaP compound semiconductor is a semiconductor having an indirect transition type band structure, and shows low transition probability, and thus has difficulty in elevation of the light emission efficiency. In light of this, development of LEDs having an emission wavelength in the visible light range is advanced by using a material based on a nitride semiconductor which is a direct transition type semiconductor.

Regarding emission in the visible light range, it is known that elevation in efficiency is difficult and the light emission efficiency significantly decreases particularly in the wavelength region of greater than or equal to 530 nm. FIG. 15 is a graph showing the relation between the peak emission wavelength and the internal quantum efficiency, and the horizontal axis corresponds to the peak emission wavelength, and the vertical axis corresponds to the internal quantum efficiency (IQE). According to FIG. 15, it can be confirmed that the internal quantum efficiency suddenly decreases as the peak emission wavelength exceeds 520 nm. The wavelength region in which the internal quantum efficiency decreases as described above is called a “green gap region,” and the decrease in efficiency in such a wavelength region is problematic irrespectively of the GaP or nitride semiconductor. This leads to the demand of elevating the internal quantum efficiency in the green gap region to improve the light emission efficiency.

As one reason for the decrease in light emission efficiency, particularly, in the wavelength region of greater than or equal to 530 nm, decrease in recombination probability between an electron and a hole in the active layer caused by a piezo electric field can be recited. This point is now described by taking a nitride semiconductor as an example.

A nitride semiconductor such as GaN or AlGaN has a wurtzite crystal structure (hexagonal crystal structure). Regarding faces of the wurtzite crystal structure, the crystal face and the orientation are expressed by using fundamental vectors represented by a1, a2, a3 and c according to the 4 exponential notation (hexagonal crystal index). The fundamental vector c extends in the direction of [0001], and this direction is called “c-axis.” The face perpendicular to the c-axis is called “c-plane” or “(0001) face.”

Conventionally, in production of a semiconductor light-emitting element using a nitride semiconductor, a substrate having a c-plane substrate as the main face is used as a substrate on which nitride semiconductor crystals are to be grown. Actually, a GaN layer is grown on this substrate at a low temperature, and further a nitride semiconductor layer is grown above the GaN layer. As an active layer that constitutes a layer contributing to light emission, InGaN which is a mixed crystal of GaN and InN is commonly used.

Here, there is a difference in lattice constant between GaN and InN. To be more specific, regarding the a-axial direction, the lattice constant of GaN is 0.3189 nm, and the lattice constant of InN is 0.354 nm. Therefore, when an InGaN layer containing InN having a larger lattice constant than GaN is grown above the GaN layer, the InGaN layer receives a compressive strain in the direction perpendicular to the growing face. At this time, the balance of polarization between Ga and IN having positive charge and N having negative charge is disrupted, and an electric field along the c-axis is generated (piezo electric field). As the piezo electric field is generated in the active layer, the band of the active layer bends and the degree of overlapping between wave functions of the electron and the hole decreases, so that the recombination probability between the electron and the hole in the active layer decreases (so-called “quantum-confined Stark effect”). As a result, the internal quantum efficiency decreases.

For the purpose of achieving the emission wavelength of greater than or equal to 530 nm, it is necessary to increase the In composition contained in the active layer so as to realize a band gap energy suited for the wavelength. However, when the In composition is increased, the compressive strain increases, and thus the piezo electric field increases. This results in further deterioration in the internal quantum efficiency.

In light of these problems, studies are made about a light-emitting element that prevents generation of a piezo electric field in the active layer by growing the active layer using a substrate having a nonpolar face, e.g., a (10-10) face called an m-face that is perpendicular to the [10-10] direction as a superficial face (see, for example, Patent Document 1).

### PRIOR ART DOCUMENT

### Patent Document

Patent Document 1: JP-A-2013-230972

### SUMMARY OF THE INVENTION

### Problems to be Solved by the Invention

However, in other wavelength regions such as 365 nm, higher light emission efficiency is shown when the active layer is grown in the c-axial direction, and a similar effect is expected in the wavelength region of more than or equal to 530 nm as far as the problem of the piezo electric field can be alleviated. From such a point, it is an object of the present invention to elevate the light emission efficiency than ever before in the semiconductor light-emitting element having a peak emission wavelength of greater than or equal to 530 nm formed by growing the active layer in the c-axial direction.

### Means for Solving the Problem

The present invention provides a semiconductor light-emitting element having a peak emission wavelength of greater than or equal to 530 nm, including:

an n-type semiconductor layer;

a superlattice layer formed above the n-type semiconductor layer and composed of a laminate of a plurality of nitride semiconductors having different band gaps;

an active layer formed above the superlattice layer; and

a p-type semiconductor layer formed above the active layer,

wherein in the active layer, a first layer composed of In_{X1}Ga_{1-X}N (0 ≦X1≦0.01), a second layer composed of In_{X2}Ga_{1-X2}N (0.2<X2<1), and a third layer composed of Al_{Y1}Ga_{1-Y1}N (0<Y1<1) are laminated, and at least the first layer and the second layer are formed cyclically. In the following, the notation of “AlGaN,” “InGaN” or the like is appropriately used when the composition is not required to be specifically indicated.

AlGaN that forms the third layer is a mixed crystal of GaN and AlN, and the balance of polarization between Ga and Al having positive charge and N having negative charge is disrupted due to difference in crystal size and the like, and an electric field along the c-axis is generated (spontaneous polarization). The electric field by the spontaneous polarization of AlGaN is applied to the direction opposite to InGaN, with the result that the electric field derived from AlGaN is generated in the direction of cancelling the piezo electric field derived from InGaN. That is, by having the third layer in which the active layer is composed of AlGaN, the piezo electric field generated with respect to the active layer is alleviated, and a bend of the band of the active layer can be made smaller than ever before. As a result, decrease in the recombination probability between an electron and a hole in the active layer is alleviated than ever before, and the internal quantum efficiency is improved.

In addition, between the n-type semiconductor layer and the active layer, a superlattice layer composed of a laminate of a plurality of nitride semiconductors having different band gaps is provided. Accordingly, it becomes possible to distort the crystal, and the effect of alleviating the lattice distortion of the active layer including the second layer composed of InGaN having a high In composition is obtained.

As described above, it is necessary to increase the In composition of InGaN contained in the active layer so as to realize the peak emission wavelength of greater than or equal to 530 nm. In order to increase the In composition in InGaN, it is necessary to set the temperature lower than the temperature at which GaN is grown. This requirement is more significant as the In composition increases because the vapor pressure of InGaN is low, and In becomes difficult to be taken into crystals when the growth temperature is high. For example, in comparison with the case of forming an active layer emitting blue light having a peak emission wavelength of about 450 nm, it is necessary to lower the growth temperature by about 50° C. so as to realize an active layer emitting light having a peak emission wavelength of greater than or equal to 530 nm.

By the way, in a conventional semiconductor light-emitting element, it is general to provide an electron block layer (also called EB layer) between the active layer and the p-type semiconductor layer. The EB layer is provided for the purpose of preventing the electrons injected into the active layer from the n-type semiconductor layer from going over the active layer and entering the p-type semiconductor layer (also called “overflow”) to decrease the recombination probability. In order to increase the carrier injection efficiency into the active layer, the barrier layer of the active layer is sometimes doped with Si, and at this time the overflow phenomenon appears significantly.

The reason is as follows. Since the n-type semiconductor layer that is grown prior to the active layer has low activation energy, high activation yield of an n-type impurity (such as Si) is realized. On the other hand, as described above, the p-type semiconductor layer that is grown after formation of the active layer containing InGaN has high activation energy and is required to grow at a low temperature, so that the activation yield of the p-type impurity (such Mg) is low. As a result, the concentration of the n-type impurity is higher than the concentration of the p-type impurity, and the number of electrons that fail to recombine with holes and overflow increases.

From the view point of preventing such a phenomenon, it is very useful to provide an electron block layer between the active layer and the p-type semiconductor layer in the conventional configuration.

Specifically, by using a material having a larger energy band gap than other layers do, such as the active layer or the p-type semiconductor layer as the electron block layer, a barrier against electrons flowing from the active layer to the p-type semiconductor layer is formed. This aims at preventing the electrons injected from the n-type semiconductor layer from overflowing into the p-type semiconductor layer, and confining the electrons in the active layer, and thus preventing decrease in recombination probability.

As described above, for realizing the peak emission wavelength of greater than or equal to 530 nm, it is necessary to lower the growth temperature of the active layer so as to increase the In composition. Therefore, the growth temperature of the electron block layer needs to be lowered under the influence of this temperature reduction. This is because if the growth temperature of the electron block layer is set high, InGaN forming the active layer cannot bear the high temperature, and the crystals can be broken.

A conventional electron block layer is composed of p-AlGaN. However, when AlGaN is grown at a low temperature, Al is not sufficiently taken into GaN due to the parasitic reaction between group III and group V, so that not only AlGaN having a high Al composition is not formed but also pits are generated due to abnormal growth to lead to deterioration of the film quality. As a result, the element resistance rises. There is a case where Mg is doped so as to render the electron block layer p-type. However, when the electron block layer doped with Mg is grown at a low temperature, activation yield of Mg also decreases. Thus, the element resistance rises also in this case. Moreover, the generated pit forms a non-radiative center to deteriorate the light output when the same current is supplied.

According to the configuration of the present invention, the third layer composed of AlGaN is provided as the active layer. The band gap energy of GaN is about 3.4 eV, the band gap energy of InN is about 0.7 eV, and the band gap energy of MN is about 6.2 eV. Therefore, in the active layer, the first layer composed of InGaN having low GaN or In ratio forms the barrier layer, and the second layer composed of InGaN having higher In ratio than the first layer does forms the light-emitting layer, and the third layer composed of AlGaN has a higher energy band gap than the first layer does, and thus functions as a layer for realizing the function of interfering with migration of electrons.

That is, the third layer has not only the function of alleviating the piezo electric field of InGaN as described above, but also the function of controlling overflow of electrons from the n-type semiconductor layer into the p-type semiconductor layer over the active layer. As a result, the decrease in recombination probability between an electron and a hole in association with the overflow of electrons is alleviated without necessity of separately providing the electron block layer as in the conventional case. Therefore, even when the In composition of the second layer is increased, crystals of InGaN will not be broken in the subsequent growth process, and it is possible to realize a semiconductor light-emitting element having high light emission efficiency and having a peak emission wavelength of greater than or equal to 530 nm.

In the above configuration, the second layer can be composed of In_{X2}Ga_{1-X2}N (0.28≦X2≦0.33) having a film thickness of greater than or equal to 2.4 nm and less than or equal to 2.8 nm.

In general, it is known that the external quantum efficiency of the semiconductor light-emitting element improves as the density of the injected current decreases, and the emission wavelength shifts to the side of the long wavelength. However, since the market requests the miniaturization of elements, there is a high demand of realizing a semiconductor light-emitting element that shows a peak emission wavelength of greater than or equal to 530 nm even if a current of high density is injected.

When the second layer was configured in the condition of the above numerical value range, a light-emitting element having a peak emission wavelength of greater than or equal to 530 nm, particularly a peak emission wavelength of greater than or equal to 540 nm and less than or equal to 570 nm was realized even when the density of the injected current was as high as 50 A/cm². Also when the density of the injected current was 25 A/cm², a light-emitting element of high output was realized.

In the above configuration, letting a film thickness of the first layer be T1, a film thickness of the second layer be T2, and a film thickness of the third layer be T3, the active layer can be configured so that relations of 5T2≦T1≦10T2 and T3<T2 are satisfied.

As described above, the second layer composed of InGaN having a high In ratio is required to be grown at a low growth temperature. Since the active layer has such a configuration that the first layer, the second layer and the third layer are laminated, and at least the first layer and the second layer are cyclically laminated, there is inevitably a necessity of growing the first layer and the third layer at a low temperature that is similar to the growth temperature of the second layer.

Here, when the first layer composed of InGaN having a low GaN or In ratio is grown at a growth temperature that is as low as a growth temperature for the second layer, the quality of crystal deteriorates, and the light output decreases. However, when the first layer has a certain degree of film thickness, the crystal two-dimensionally grows to be able to form excellent steps, and the crystal quality is ameliorated. However, when the thickness of the first layer is too large, impairment of the surface morphology caused by the low temperature growth leads the deterioration in the light output. Therefore, by selecting the film thickness T1 of the first layer so that 5T2≦T1≦10T2 is satisfied, it is possible to realize a high light output.

Further, since the third layer also having the function of preventing overflow of electrons has a higher energy band gap than the first layer and the second layer do as described above, the electrons cannot be migrated to the side of the p-type semiconductor layer unless they are tunneled in the third layer. Therefore, it is necessary to form the third layer to have a relatively small film thickness. By forming the third layer to have a film thickness smaller than the film thickness of the second layer constituting the light-emitting layer, it becomes possible to make electrons tunnel reliably in the third layer.

Here, as described above, since the film thickness of the second layer can be greater than or equal to 2.4 nm and less than or equal to 2.8 nm, the film thickness of the first layer can be greater than or equal to 12 nm and less than or equal 28 nm on the basis of this range.

Further, the active layer may have such a configuration that the first layer, the second layer and the third layer are cyclically formed in a position near the p-type semiconductor layer, and the first layer and the second layer are cyclically formed in a position near the n-type semiconductor layer.

The third layer composed of AlGaN has large band gap energy, and the first layer has smaller band gap energy than the third layer does. Since AlGaN has an electric field due to the spontaneous polarization as described above, distortion occurs in the energy band. As a result, in the vicinity of the joint face between the third layer and the first layer, a groove is formed in the band chart of the valence band of the active layer, and holes are two-dimensionally accumulated in the groove (also referred to as “two-dimensional hole gas”). Since these holes have high mobility in the two-dimensional direction, there is a possibility of occurrence of an overflow phenomenon in which holes injected into the active layer from the side of the p-type semiconductor layer go over the active layer.

When the overflow phenomenon of holes occurs, the holes are accumulated in the InGaN region of the superlattice layer of GaN/InGaN formed between the active layer and the n-type semiconductor layer. As a result, an electron injected from the n-type semiconductor layer recombines with a hole in the superlattice layer, and the light with an undesired wavelength is generated. This is not desired because the light showing a peak wavelength different from the peak wavelength of the light generated in the active layer is generated. In particular, when the desired wavelength is greater than or equal to 530 nm, higher light output compared, for example, with blue light is not obtained. Thus, even if the light having a different peak wavelength (undesired light) occurs at low output, the output ratio of the undesired light to the light of the desired wavelength shows a relatively high value.

According to the above configuration, since the third layer is provided on the side of the p-type semiconductor layer, alleviation of the piezo electric field derived from InGaN and control of overflow of electrons are realized as described above. Meanwhile, since the third layer is not provided on the side of the n-type semiconductor layer, two-dimensional hole gas having high mobility is not formed and overflow of holes is controlled.

Moreover, in addition to the above configuration, the configuration having a hole barrier layer composed of a nitride semiconductor layer between the superlattice layer and the active layer may be employed. According to this configuration, since entry of holes overflowing the active layer into the superlattice layer is controlled, generation of undesired light in the superlattice layer of GaN/InGaN is controlled as described above.

Specifically, the hole barrier layer can be composed of a nitride semiconductor layer having a Si concentration of greater than or equal to 5×10¹⁸/cm³ and less than or equal to 5×10¹⁹/cm³. As a result, the energy band gap between the superlattice layer and the active layer is sufficiently expanded, and thus migration of holes overflowing the active layer to the side of the superlattice layer is interfered with. The higher the Si concentration is, the more the energy band between the superlattice layer and the active layer can be flattened. This is because when an impurity level of high concentration is formed, the valence band is screened by a free carrier, and thus the energy band is flattened. As a result, the energy band gap expands, and the effect of interfering with migration of holes to the side of the superlattice layer is improved. However, when the Si concentration is more than 5×10¹⁹/cm³, the surface of the nitride semiconductor layer is roughed, and thus the Si concentration is preferably more than or equal to ×10¹⁸/cm³ and less than or equal to 5×10¹⁹/cm³. In order to realize the nitride semiconductor layer showing a very high Si concentration of greater than or equal to 1×10¹⁹/cm³ as a hole barrier layer with a good surface condition, it is preferred to use AlGaN.

The third layer can be composed of Al_{Y1}Ga_{1-Y1}N (0.2≦Y1≦0.5). When the Al composition of the third layer is lower than 20%, the effect of alleviating the piezo electric field derived from InGaN of the second layer in the active layer is not sufficiently obtained. On the other hand, an Al composition of the third layer of higher than 50% is not preferred because the electric field by the spontaneous polarization of AlGaN is too strong.

The n-type semiconductor layer can be composed of AlGaN having a Si concentration of more than or equal to 3×10¹⁹/cm³.

In the case of using GaN as the n-type semiconductor layer, the following phenomenon is known: film roughing occurs due to impairment in the condition of the atomic bond when the concentration of Si to be injected as an n-type dopant is greater than or equal to 1×10¹⁹/cm³. Due to the impairment in crystal condition caused by the film roughing, not only the specific resistance does not sufficiently decrease even when Si is doped in a very high concentration, but also the surface becomes rough and cloudy.

On the other hand, when the n-type semiconductor layer is AlGaN, it was confirmed that the problem of film roughing does not occur even when the Si concentration is greater than or equal to 3×10¹⁹/cm³, more specifically greater than or equal to 7×10¹⁹/cm³. As a result, it becomes possible to decrease the resistance of the n-type semiconductor layer, and thus it is possible to make the current required for light emission flow in the light-emitting layer even at a low operation voltage, and to improve the light emission efficiency.

In the above configuration, the superlattice layer may be composed of a laminate of a fourth layer and a fifth layer, the fifth layer may be an InGaN layer, and the fourth layer may be a GaN layer, or an InGaN layer having a lower In composition than the fifth layer does.

### Effect of the Invention

According to the present invention, it is possible to realize a semiconductor light-emitting element having a higher light emission efficiency, and having a peak emission wavelength of greater than or equal to 530 nm, while growing an active layer in the c-axial direction.

### BRIEF DESCRIPTION OF THE DRAWINGS

FIGS. 1(a) to 1(c) are section views schematically showing a structure of a first embodiment of a semiconductor light-emitting element.

FIGS. 2(a) and 2(b) are section views schematically showing a structure of Comparative Example.

FIG. 3A is a SEM image of a layer surface of GaN when the Si concentration is 1.5×10¹⁹/cm³.

FIG. 3B is an AFM image of a layer surface of AlGaN when the Si concentration is 7×10¹⁹/cm³.

FIG. 4 is a graph in which a relation between the Si concentration of AlGaN and the specific resistance at room temperature is plotted.

FIG. 5 is a graph showing a comparison of I-V characteristics of the semiconductor light-emitting element between Example and Comparative Example.

FIGS. 6(a) and 6(b) are images showing a comparison of the surface condition between a case where an electron block layer is formed and a case where the same is not formed after formation of the active layer.

FIG. 7 is a graph showing a comparison of I-L characteristics of the semiconductor light-emitting element between Example and Comparative Example.

FIG. 8A is an energy band chart of the semiconductor light-emitting element corresponding to Comparative Example.

FIG. 8B is an energy band chart of the semiconductor light-emitting element corresponding to Example.

FIG. 9 is a graph showing a relation between the film thickness of a first layer and the light output.

FIG. 10A is a graph showing a relation between the film thickness of a second layer and the light output when the current density is 25 A/cm².

FIG. 10B is a graph showing a relation between the film thickness of the second layer and the light output when the current density is 50 A/cm².

FIG. 11 is a graph showing a comparison of the light output of a semiconductor light-emitting element including an undoped first layer, and the light output of a semiconductor light-emitting element including a Si-doped first layer.

FIG. 12 is a section view schematically showing a structure of a second embodiment of the semiconductor light-emitting element.

FIG. 13 is an energy band chart in a configuration of the second embodiment of the semiconductor light-emitting element.

FIG. 14 is an energy band chart in a configuration of a third embodiment of the semiconductor light-emitting element.

FIG. 15 is a graph showing a relation between the peak emission wavelength and the internal quantum efficiency.

### MODE FOR CARRYING OUT THE INVENTION

The semiconductor light-emitting element of the present invention and a method for producing the same will be described with reference to drawings.

In the following drawings, the dimensional ratio in the drawing and the actual dimensional ratio do not necessarily coincide with each other. In the following description, the numerical values regarding the impurity concentration, film thickness, composition, and the number of cycles of a multilayer structure are merely examples, and they are not given for limitation. The description “AlGaN” is synonymous with the description of AlₘGa₁₋ₘN (0<m<1), and describes the composition ratio of Al to Ga merely in an abbreviated form, and is not intended to limit the case where the composition ratio between Al and Ga is 1:1. The same applies to the description “InGaN.”

Moreover, in this description, regarding the directions perpendicular to the principal plane, the one is defined as “above” and the other is defined as “below.” However, these are definitions for convenience of description, and it is not intended to exclude the configuration obtained by turning the element upside down. In the description regarding an element, the description “above one layer A, another layer B is formed” is intended to include the configuration in which layer B is situated above layer A by turning the element upside down.

### First Embodiment

A first embodiment of the semiconductor light-emitting element of the present invention will be described.

### [Structure]

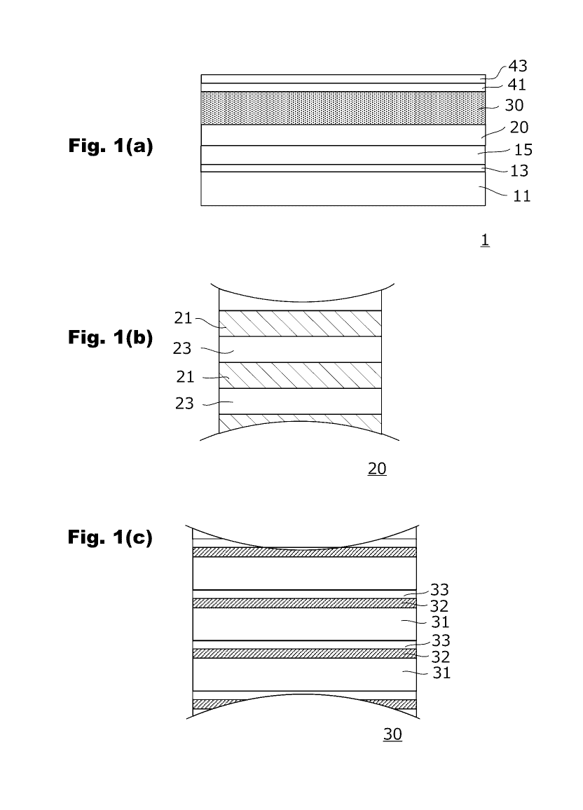

FIGS. 1(a) to 1(c) are section views schematically showing a structure of the first embodiment of the semiconductor light-emitting element of the present invention. FIG. 1(a) is a section view schematically showing a configuration of a semiconductor light-emitting element 1. The semiconductor light-emitting element 1 has an n-type semiconductor layer 15, a superlattice layer 20 of GaN/InGaN formed on the upper face of the n-type semiconductor layer 15, an active layer 30 formed on the upper face of the superlattice layer 20, and a p-type semiconductor layer 43 formed above the active layer 30 (an undoped GaN layer 41 will be described later). FIG. 1(b) is a section view schematically showing a configuration of the superlattice layer 20, and FIG. 1(c) is a section view schematically showing a configuration of the active layer 30.

The semiconductor light-emitting element 1 has a substrate 11, an undoped GaN layer 13 is formed on the upper face of the substrate 11, and the n-type semiconductor layer 15 is formed on the upper face of the undoped GaN layer 13. The substrate 11 is formed of a sapphire substrate or a GaN substrate.

The undoped GaN layer 13 is a layer formed by epitaxial growth on a c-plane of the substrate 11, and has a film thickness of, for example, 3000 nm.

The n-type semiconductor layer 15 is formed on the upper face of the undoped GaN layer 13. In the present embodiment, the n-type semiconductor layer 15 has a film thickness of 2000 nm, and is formed of AlGaN having a concentration of Si as an n-type dopant of 3×10¹⁹/cm³, and an Al composition of 5%.

The superlattice layer 20 is composed of GaN/InGaN, and is formed on the upper face of the n-type semiconductor layer 15. In the present embodiment, a GaN layer 21 and an InGaN layer 23 both having a thickness of 2.5 nm are laminated in ten cycles to form the superlattice layer 20. The In composition of the InGaN layer 23 is 7%, and both the GaN layer 21 and the InGaN layer 23 are doped with Si in a concentration of 1×10¹⁸/cm³ and are of the n-type.

In the present embodiment, the active layer 30 is formed by laminating a first layer 31 composed of In_{X1}Ga_{1-X1}N (0≦X1≦0.01), a second layer 32 composed of In_{X2}Ga_{1-X2}N (0.2<X2<1), and a third layer 33 composed of Al_{Y1}Ga_{1-Y1}N (0<Y1<1) in five cycles. In one specific example, the first layer 31 is formed of undoped GaN having a film thickness of 20 nm, the second layer 32 is formed of undoped InGaN having a film thickness of 2.6 nm and an In composition of 28%, and the third layer 33 is formed of undoped AlGaN having a film thickness of 1.5 nm and an Al composition of 45%.

Since the band gap energy of GaN is about 3.4 eV, and the band gap energy of InN is about 0.7 eV, the first layer 31 composed of InGaN having a GaN or In ratio of less than or equal to 1% constitutes a barrier layer, and the second layer 32 composed of InGaN having a higher In ratio than the first layer 31 does constitutes a light-emitting layer. Moreover, since the band gap energy of AlN is about 6.2 eV, the third layer 33 composed of AlGaN has a higher energy band gap than the first layer 31 does, and exerts the function of interfering with migration of electrons as will be described later.

In the present embodiment, the undoped GaN layer 41 is formed on the upper face of the active layer 30. The undoped GaN layer 41 constitutes the final barrier layer. The undoped GaN layer 41 may be included in the active layer 30. The undoped GaN layer 41 is formed, for example, in a film thickness of 20 nm likewise the first layer 31 in the active layer 30.

On the upper face of the undoped GaN layer 41, the p-type semiconductor layer 43 is formed. In the present embodiment, the p-type semiconductor layer 43 has a film thickness of 100 nm, and is composed of p-GaN having a concentration of Mg as a p-type dopant of 3×10¹⁹/cm³. A p-type contact layer of high concentration can be formed above the p-GaN as necessary.

### [Verification]

The effect by the semiconductor light-emitting element 1 having the above configuration is verified. The semiconductor light-emitting element 1 formed in the above numerical value conditions is described hereinafter as “Example.”

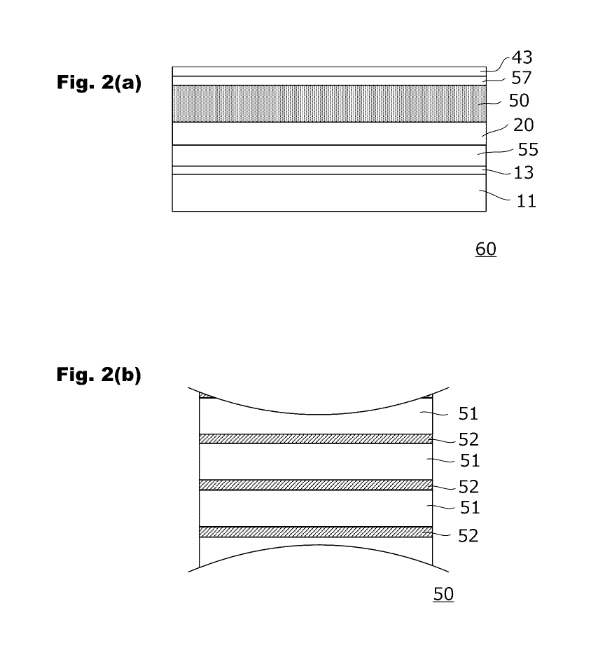

FIGS. 2(a) and 2(b) are section views schematically showing a structure of Comparative Example for comparison with Example. The same constituent as that in FIG. 1 is denoted by the same reference numeral. FIG. 2(a) is a section view schematically showing a configuration of a semiconductor light-emitting element 60 of Comparative Example. The semiconductor light-emitting element 60 of Comparative Example has the substrate 11, and above the substrate 11, an n-type semiconductor layer 55 is formed via the undoped GaN layer 13. Unlike the n-type semiconductor layer 15 of Example, the n-type semiconductor layer 55 is composed of n-GaN.

The semiconductor light-emitting element 60 of Comparative Example has the superlattice layer 20 of InGaN/GaN on the upper face of the n-type semiconductor layer 55, and an active layer 50 on the upper face of the superlattice layer 20. The active layer 50 has a configuration in which a GaN layer 51 and an InGaN layer 52 are cyclically laminated, and five cycles are employed here likewise in Example. FIG. 2(b) is a section view schematically showing a configuration of the active layer 50. The film thickness of the GaN layer 51 is 20 nm likewise in the first layer 31 of Example, and the film thickness of the InGaN layer 52 is 2.5 nm likewise in the second layer 32 of Example. That is, the semiconductor light-emitting element 60 of Comparative Example does not have a layer corresponding to the third layer 33 composed of AlGaN unlike the semiconductor light-emitting element 1 of Example.

The semiconductor light-emitting element 60 of Comparative Example has an electron block layer 57 composed of p-AlGaN on the upper face of the active layer 50, and has the p-type semiconductor layer 43 composed of p-GaN on the upper face of the electron block layer 57.

### (Evaluation of I-V Characteristics)

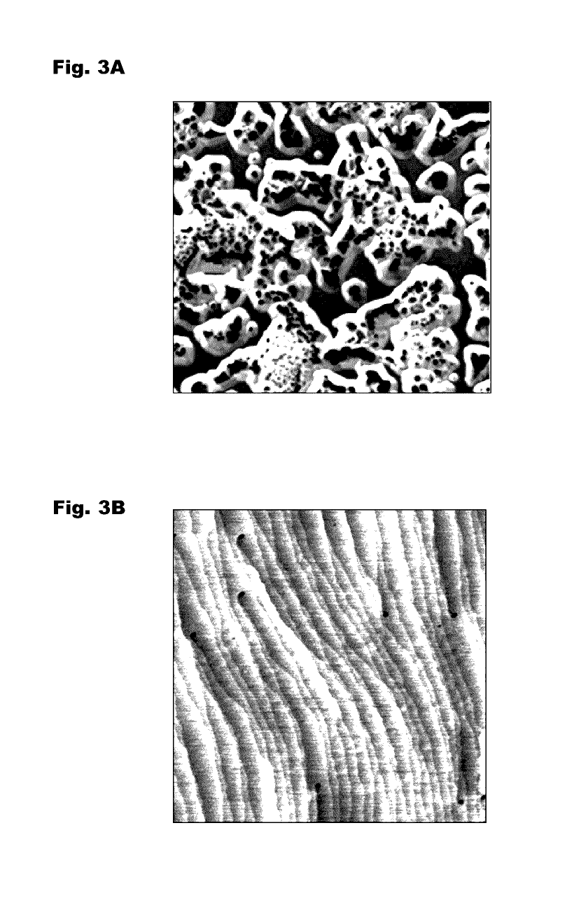

As provided in the semiconductor light-emitting element 60 of Comparative Example, GaN is conventionally used as the n-type semiconductor layer 55. In doping with Si in high concentration so as to render GaN an n-type, the phenomenon of occurrence of film roughing due to, for example, impairment in the condition of the atomic bond is known at a Si concentration of greater than or equal to 1×10¹⁹/cm³. FIG. 3A is an image of the layer surface of GaN taken by a SEM (Scanning Electron Microscope) when the Si concentration is 1.5×10¹⁹/cm³, and occurrence of roughing on the surface is observed. Roughing of the surface was observed also when the impurity concentration was 1.3×10¹⁹/cm³ or 2.0×10¹⁹/cm³.

On the other hand, as the n-type semiconductor layer 15, AlGaN is used as described above. In the case of AlGaN, film roughing does not occur even when the doped Si concentration is larger than 1×10¹⁹/cm³. FIG. 3B is an image of the layer surface of AlGaN taken by an AFM (Atomic Force Microscopy) when the Si concentration was 7×10¹⁹/cm³. According to FIG. 3B, in the case of AlGaN, a stepwise surface (atomic step) is observed even when the Si concentration is 7×10¹⁹/cm³, revealing that roughing does not occur on the layer surface. Even when the Si concentration was 2×10²⁰/cm³, an image similar to that in FIG. 3B was obtained. Also when the compositions of Al and Ga as constituting materials were varied, and Si was doped in a high concentration as described above, occurrence of roughing on the layer surface was not observed when Si was doped in high concentration as described above.

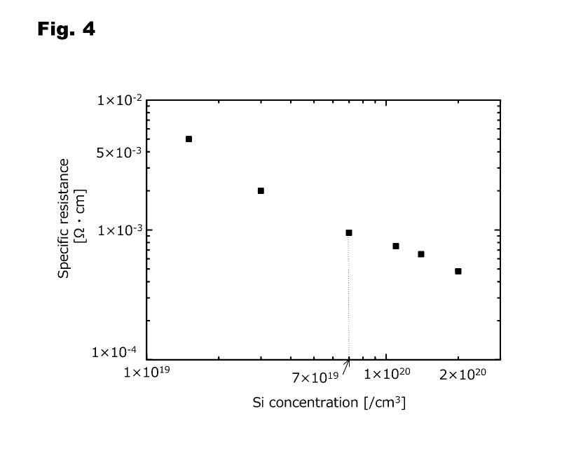

FIG. 4 is a graph in which a relation between the Si concentration of AlGaN and the specific resistance when the Si concentration of AlGaN is varied under room temperature is plotted. The specific resistance was measured by using a commonly used hole measuring device.

According to FIG. 4, it can be found that as the concentration of Si to be doped in AlGaN increases, the specific resistance decreases. When film roughing occurs, the resistance rises due to this roughing, and hence, the specific resistance is expected to start increasing from the Si dope concentration value at which the film roughing occurs. That is, according to this result, it is suggested that film roughing does not occur in AlGaN even when the Si concentration is raised to 2×10²⁰/cm³.

When the Si dope concentration for GaN was 9×10¹⁸/cm³, which is near 1×10¹⁹/cm³ as the upper limit value at which film roughing does not occur, the specific resistance was 5×10⁻³ Ωcm. That is, when GaN is used, it is impossible to largely decrease the specific resistance from this value.

According to FIG. 4, since the semiconductor light-emitting element 1 of Example is provided with the n-type semiconductor layer 15 composed of AlGaN, the Si concentration can be greater than or equal to 3×10¹⁹/cm³, and the specific resistance can be far less than the lower limit value of the specific resistance of the conventional GaN. As a result, it is possible to decrease the element resistance, and to decrease the necessary voltage.

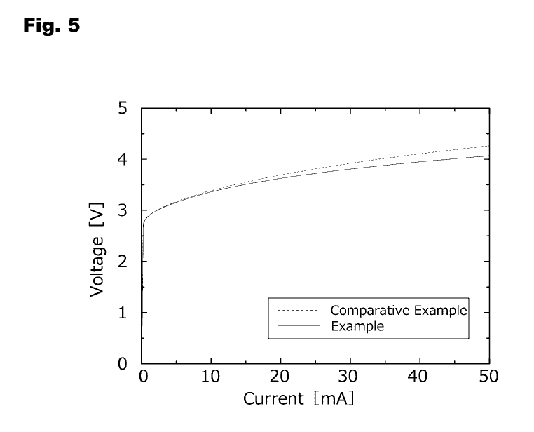

FIG. 5 is a graph showing a comparison of current/voltage characteristics (I-V characteristics) between the semiconductor light-emitting element 1 of Example and the semiconductor light-emitting element 60 of Comparative Example. According to FIG. 5, a certain current value is realized at a lower voltage in Example than in Comparative Example. This reveals that according to the semiconductor light-emitting element 1 in which the n-type semiconductor layer 15 is composed of AlGaN, a sufficient current amount is ensured and high light emission efficiency can be realized even under a low voltage condition.

### (Evaluation of I-L Characteristics)

The semiconductor light-emitting element 60 of Comparative Example has the electron block layer 57. As is described above in the section of “MEANS FOR SOLVING THE PROBLEMS,” the electron block layer 57 is provided for the purpose of preventing an electron injected from the n-type semiconductor layer 55 into the active layer 50 from entering the p-type semiconductor layer 43 over the active layer 50, and suppressing decrease of the recombination probability in the active layer 50. The electron block layer 57 is composed of AlGaN having a higher energy band gap than the active layer 50 and the p-type semiconductor layer 43 do so as to form a barrier against the electron flowing from the active layer 50 to the p-type semiconductor layer 43.

Here, as described above, the active layer 50 has the InGaN layer 52, and in order to make the peak wavelength of the light generated in the active layer 50 greater than or equal to 530 nm, it is necessary to increase the In composition of the InGaN layer 52 to about 30%. However, for achieving this, it is necessary to make the growth temperature of the InGaN layer 52 lower than the growth temperature of general GaN, and the same also applies after formation of the InGaN layer 52. In other words, in forming the electron block layer 57, it is necessary to grow AlGaN at a low temperature within the range in which crystals of the InGaN layer 52 are not broken. However, in association with this, Al is not sufficiently taken into GaN due to parasitic reaction between group III and group V, and pits are generated, and the film quality deteriorates.

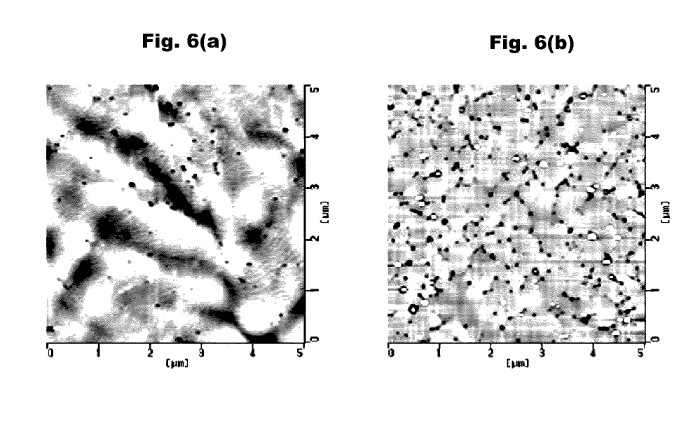

FIGS. 6(a) and 6(b) are images showing a comparison of the surface condition between a case where the electron block layer 57 is formed and a case where the electron block layer 57 is not formed after formation of the active layer 50 which is a laminate of the InGaN layer 52 and the GaN layer 51 in the condition that the In composition of the InGaN layer 52 is 30%. FIG. 6(a) is an image of a surface condition in the condition that the active layer 50 is formed. FIG. 6(b) is an image of a surface condition in a case where the electron block layer 57 composed of AlGaN is formed in a temperature condition within the range where the crystal condition of the InGaN layer 52 will not be broken (for example, about 880° C.) after formation of the active layer 50. Both of these are images taken by an AFM (Atomic Force Microscopy).

In the image of FIG. 6(b), a much greater number of black dots are observed on the surface in comparison with the image of FIG. 6(a). These black dots correspond to pits. In other words, the image reveals that a great number of pits are formed when AlGaN is formed as the electron block layer 57. This suggests occurrence of a parasitic reaction as a result of growing AlGaN at a low temperature.

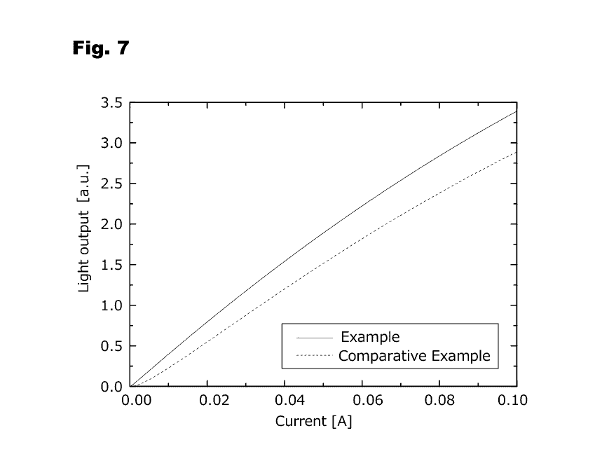

FIG. 7 is a graph showing a comparison of current/light output characteristics (I-L characteristics) between the semiconductor light-emitting element 1 of Example and the semiconductor light-emitting element 60 of Comparative Example. FIG. 7 shows that higher light output is realized in Example than in Comparative Example in the condition that the same current is supplied.

As described above, in the semiconductor light-emitting element 60 of Comparative Example, many pits (defects) would be formed in the electron block layer 57. Accordingly, it is inferred that the pits function as non-radiative centers to deteriorate the light emission efficiency.

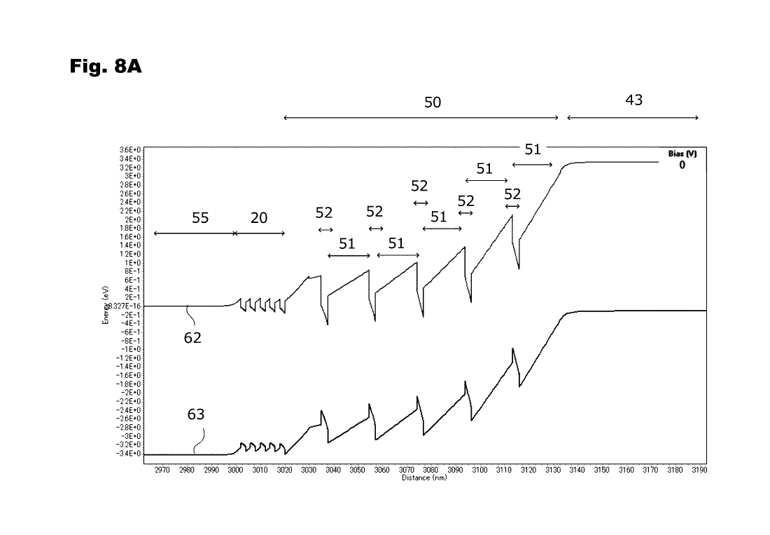

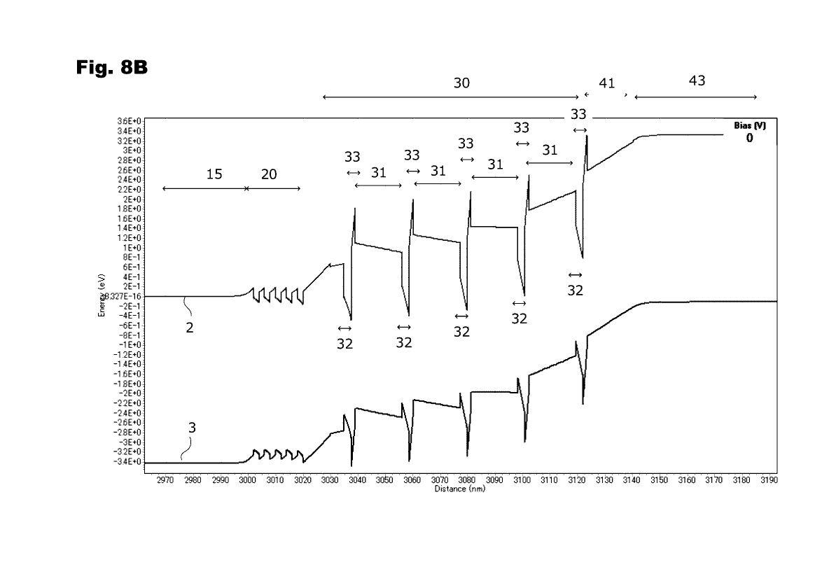

In contrast to this, in the semiconductor light-emitting element 1 of Example, higher light output is realized than in the semiconductor light-emitting element 60 of Comparative Example. This suggests that by providing the active layer 30 possessed by the semiconductor light-emitting element 1 of Example with the third layer 33 composed of AlGaN, overflow of electrons is controlled without necessity of providing the electron block layer 57. The reason for this will be described with reference to the energy band charts of FIG. 8A and FIG. 8B.

FIG. 8A is an energy band chart of the element not having the third layer 33 composed of AlGaN in the active layer 50 (the element corresponds to Comparative Example), and FIG. 8B is an energy band chart of the element having the active layer 30 including the third layer 33 composed of AlGaN (the element corresponds to Example). Both of these energy band charts show a condition where the applied bias is 0 V. In FIG. 8A, an energy band chart for a configuration not having the electron block layer 57 is shown for convenience of description.

According to the energy band chart of FIG. 8A, when a voltage is applied to the element, electrons flow toward the side of the p-type semiconductor layer 43 from the side of the n-type semiconductor layer 55. At this time, even when electrons are accumulated in the well region constituted by the InGaN layer 52, they sequentially pass through the well region of the InGaN layer 52 at high probability while they are pushed out by the following electrons having high mobility. As a result, the probability that an electron and a hole recombine by the well region decreases, and the light emission efficiency decreases. For occurrence of such a phenomenon, the semiconductor light-emitting element 60 of Comparative Example is provided with the electron block layer 57. However, as described above, the light output decreases even when the electron block layer 57 is provided.

In contrast to this case, according to the energy band chart of FIG. 8B, since the active layer 30 is provided with the third layer 33 composed of AlGaN, an energy barrier caused by the third layer 33 is formed in the region of the active layer 30. When a voltage is applied to the element, and electrons flowing toward the side of the p-type semiconductor layer 43 from the side of the n-type semiconductor layer 15 are taken into the well region of the second layer 32 composed of InGaN, the electrons are interfered with by the barrier of the third layer 33 composed of AlGaN even when the following electrons having high mobility flow in. As a result, it is possible to decrease the probability that the electrons flow out to the side of the first layer 31 composed of GaN formed above. That is, since a barrier function similar to that of the electron block layer is exerted by the third layer 33 without necessity of providing the electron block layer 57 between the active layer 30 and the p-type semiconductor layer 43, high recombination probability is realized. As described above, since the third layer 33 has a very small film thickness of about 1 nm, electrons that are not recombined can tunnel through the third layer 33, and can migrate to the next second layer 32 neighboring on the side of the p-type semiconductor layer 43.

Further, according to FIG. 8A, the energy band inclines, and the overlapping between a conduction band 62 and a valence band 63 in the InGaN layer 52 decreases. This means that a bend occurs in the energy band due to the piezo electric field since the In composition of the InGaN layer 52 is high. As a result, the degree of overlapping between the wave functions of the electron and the hole decreases, and the recombination probability with the hole decreases even when electrons are accumulated in the well region of the InGaN layer 52. This also results in deterioration in light output.

For example, as can be easily understood by comparing the region of the first layer 31 in FIG. 8B with the region of the GaN layer 51 in FIG. 8A, a bend of the energy band is suppressed in FIG. 8B in comparison with FIG. 8A. This is attributed to the fact that AlGaN forming the third layer 33 causes generation of the electric field by spontaneous polarization in a direction of cancelling the piezo electric field derived from InGaN forming the second layer 32. As a result, according to the semiconductor light-emitting element 1 of Example, the overlapping region between the conduction band 2 and the valence band 3 in the second layer 32 is sufficiently ensured, so that the recombination probability between an electron and a hole can be further improved in comparison with the semiconductor light-emitting element 60 of Comparative Example.

In brief, according to the semiconductor light-emitting element 1 of the present invention, by providing the active layer 30 with the third layer 33 composed of AlGaN, it is possible to achieve both the function of weakening the piezo electric field derived from InGaN and the function of controlling overflow of electrons. As a result, the recombination probability between an electron and a hole is improved without providing an electron block layer between the active layer 30 and the p-type semiconductor layer 43, and high light emission efficiency is realized.

### (Consideration About Film Thickness of First Layer 31)

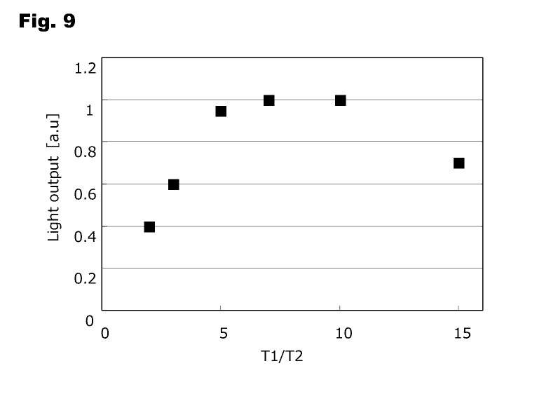

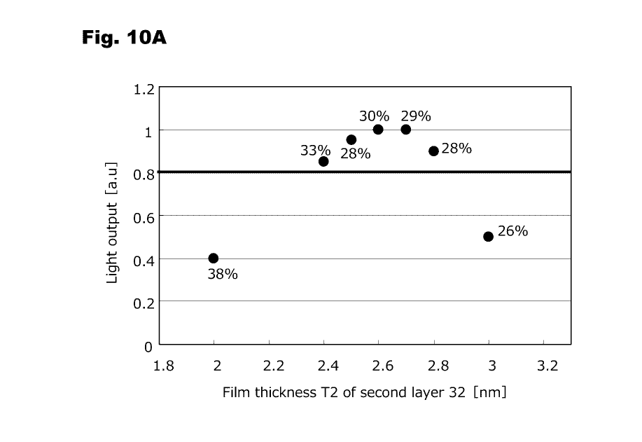

FIG. 9 is a graph in which a relation between the light output of each semiconductor light-emitting element 1 that is produced with a varying film thickness T1 of the first layer 31, and the film thickness T1 is plotted. Here, the horizontal axis is defined by a relative value of the film thickness T1 of the first layer 31 to the film thickness T2 of the second layer 32 (namely, T1/T2). Hereinafter, the film thickness T1 of the first layer 31 is simply referred to as “film thickness T1,” and the film thickness T2 of the second layer 32 is simply referred to as “film thickness T2.”

FIG. 9 indicates that in the range in which the relative value is greater than or equal to 5 and less than or equal to 10, the light output is highest, and when the relative value is more than 10 and when the relative value is less than 5, the light output deteriorates.

As described above, the second layer 32 formed of InGaN is required to grow at a temperature lower than the growth temperature of general GaN so as to achieve high In composition, and the first layer 31 is also required to grow at a low temperature so as not to break the crystal condition. Therefore, in forming the first layer 31, it is necessary to grow GaN at a temperature lower than the growth temperature of general GaN, and this leads the deterioration in quality of the GaN crystal.

However, by forming the first layer 31 to have a film thickness of a certain degree or more, the crystals become capable of growing two-dimensionally and forming excellent steps, and thus the crystal quality is ameliorated. According to FIG. 9, it is considered that by setting T1/T2 at more than or equal to 5, the crystal quality of the first layer 31 is improved, and high light output is achieved. On the other hand, forming the first layer 31 to have too large a thickness will cause deterioration in light output due to impairment of the surface morphology resulting from the low temperature growth. According to FIG. 9, the light output deteriorates when T1/T2 is 15, suggesting that the surface morphology impairs under this condition. According to FIG. 9, since the light output does not largely deteriorate when T1/T2 is greater than or equal to 5 and less than or equal to 10, it is inferred that the surface morphology does not impair at least within a range in which T1/T2 is less than or equal to 10.

From the above consideration, it can be found that the film thickness T1 of the first layer 31 is preferably greater than or equal to five times and less than or equal to ten times the value of the film thickness T2 of the second layer 32.

### (Consideration About Film Thickness of Second Layer 32)

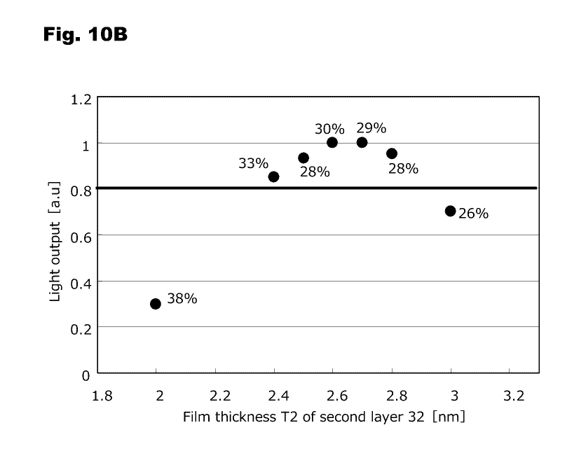

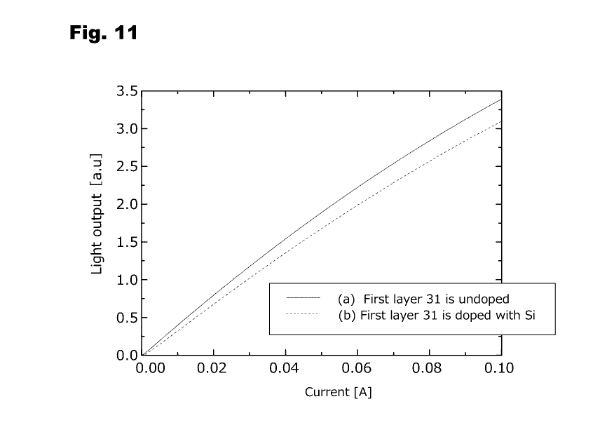

FIG. 10A and FIG. 10B are graphs in which a relation between the light output of each semiconductor light-emitting element 1 that is produced with a varying film thickness T2 of the second layer 32, and the film thickness T2 is plotted. FIG. 10A corresponds to a case where the density of the current supplied to the semiconductor light-emitting element 1 is 25 A/cm², and FIG. 10B corresponds to a case where the density of the current supplied to the semiconductor light-emitting element 1 is 50 A/cm². The numerical value appended to each plotted point indicates the value of In composition of the second layer 32.

As described above, to achieve a long peak emission wavelength of the semiconductor light-emitting element 1 such as greater than or equal to 530 nm, it is requested to increase the In composition of InGaN forming the second layer 32. By the way, as shown in the energy band chart of FIG. 8B, the film thickness of the second layer 32 decides the width of the well region of the energy band chart. Since the piezo electric field is strong in InGaN, the band of the well region formed by the second layer 32 inclines also in the semiconductor light-emitting element 1 of Example as shown in FIG. 8B. Accordingly, the band gap energy in the second layer 32 changes depending on the width of the well region, and this influences on the peak emission wavelength of the semiconductor light-emitting element 1. That is, the peak emission wavelength of the semiconductor light-emitting element 1 is influenced by the In composition and the film thickness of InGaN.

FIG. 10A and FIG. 10B compare the light output of each of the semiconductor light-emitting elements 1 that are produced to have a peak emission wavelength of greater than or equal to 540 nm and less than or equal to 570 nm by varying the film thickness and the In composition of the second layer 32, in accordance with the film thickness of the second layer 32. For example, when the film thickness of the second layer 32 is 2 nm, the In composition is 38%, when the film thickness of the second layer 32 is 2.4 nm, the In composition is 33%, and when the film thickness of the second layer 32 is 3 nm, the In composition is 26%. This simply shows that an In composition suited for the film thickness is appropriately selected because the peak emission wavelength of greater than or equal to 540 nm and less than or equal to 570 nm is not realized by simply varying only the film thickness of the second layer 32.

According to FIG. 10A and FIG. 10B, the light output of the semiconductor light-emitting element 1 largely increases in the case where the film thickness of the second layer 32 is 2.4 nm compared with the case where the film thickness is 2 nm. As the film thickness of the second layer 32 is increased to 2.5 nm or to 2.6 nm, the light output of the semiconductor light-emitting element 1 gently increases. Further, as the film thickness of the second layer 32 is increased to 2.7 nm or to 2.8 nm, the light output of the semiconductor light-emitting element 1 gently decreases. When the film thickness of the second layer 32 is 3 nm, the light output of the semiconductor light-emitting element 1 largely decreases in comparison with the case where the film thickness of the second layer 32 is 2.8 nm.

Therefore, it is suggested that high light output is realized when the semiconductor light-emitting element 1 is produced so that the film thickness of the second layer 32 is greater than or equal to 2.4 nm and less than or equal to 2.8 nm. In the case where the film thickness of the second layer 32 is greater than or equal to 2.4 nm and less than or equal to 2.8 nm, the In composition of the second layer 32 can be greater than or equal to 28% and less than or equal to 33% so that the peak emission wavelength of the semiconductor light-emitting element 1 is greater than or equal to 540 nm and less than or equal to 570 nm.

In general, it is known that the external quantum efficiency of the semiconductor light-emitting element improves as the density of the injected current decreases, and the emission wavelength shifts to the side of the long wavelength. However, by producing the semiconductor light-emitting element 1 in such a manner that the film thickness and the In composition of the second layer 32 fall within the above ranges, high light output is realized even when the density of the injected current is set as high as 50 A/cm².

### (Consideration About Doping to Active Layer)

As is already described in the section of “MEANS FOR SOLVING THE PROBLEMS,” in a conventional semiconductor light-emitting element, Si doping to the barrier layer of the active layer is sometimes conducted so as to increase the carrier injection efficiency into the active layer. The barrier layer of the active layer used herein corresponds to the first layer 31 in the semiconductor light-emitting element 1. However, in the case of the semiconductor light-emitting element 1, the light output is improved when the undoped first layer 31 is formed in comparison with the case where the first layer 31 is formed by doping with Si.

FIG. 11 is a graph showing a comparison of the light output between (a) the semiconductor light-emitting element including the undoped first layer 31, and (b) the semiconductor light-emitting element 1 including the first layer 31 doped with Si.

According to FIG. 11, the light output under the supply of the same current is higher in (a) than in (b), so that it is considered that the first layer 31 functioning as the barrier layer of the active layer 30 is preferably undoped in the structure of the semiconductor light-emitting element 1, from the view point of improving the light output. Although the reason therefor is not clear, as one inference, electrons may contrarily overflow when the entire barrier layer is doped with Si.

The superlattice layer 20 can be embodied by a laminate of a plurality of nitride semiconductors having different band gaps. In the above embodiment, the superlattice layer 20 possessed by the semiconductor light-emitting element 1 is formed of GaN/InGaN, however, it is merely one example of a laminate composed of a plurality of nitride semiconductors having different band gaps. In the case where the superlattice layer 20 is formed of a laminate of a fourth layer 21 and a fifth layer 23 (see FIG. 1(b)), it is also possible to form the fifth layer 23 of an InGaN layer, and to form the fourth layer 21 of a GaN layer, or an InGaN layer having a lower In composition than the fifth layer 23 does.

### [Production Method]

Hereinafter, a method for producing the semiconductor light-emitting element 1 will be described. The following production conditions and dimensions such as film thickness are given for illustration, and are not given for limiting the numerical values.

(Step S1)

The undoped GaN layer 13 is grown above the substrate 11. One example of a specific method is as follows.

A c-plane sapphire substrate is prepared as the substrate 11, and the substrate 11 is cleaned. More specifically, this cleaning is conducted by placing the substrate 11 (c-plane sapphire substrate) in a treatment furnace of, for example, an MOCVD (Metal Organic Chemical Vapor Deposition) device, and elevating the furnace temperature to, for example, 1150° C. while hydrogen gas is flowed at a flow rate of 10 slm in the treatment furnace.

Then, on the surface of the substrate 11, a low temperature buffer layer composed of GaN is formed, and further an underlayer composed of GaN is formed above the buffer layer to form the undoped GaN layer 13. A more specific method for producing the undoped GaN layer 13 is as follows.

First of all, the furnace pressure of the MOCVD device is set at 100 kPa, and the furnace temperature is set at 480° C. Then, while nitrogen gas and hydrogen gas each at a flow rate of 5 slm are flowed as a carrier gas in the treatment furnace, trimethylgallium (TMG) at a flow rate of 50 μmol/min and ammonia at a flow rate of 250000 μmol/min are fed as a source gas into the treatment furnace for 68 seconds. In this manner, on the surface of the substrate 11, a low temperature buffer layer composed of GaN having a thickness of 20 nm is formed.

Next, the furnace temperature of the MOCVD device is elevated to 1150° C. Then, while nitrogen gas at a flow rate of 20 slm and hydrogen gas at a flow rate of 15 slm are flowed as a carrier gas in the treatment furnace, TMG at a flow rate of 100 μmol/min and ammonia at a flow rate of 250000 μmol/min are fed as a source gas into the treatment furnace for 60 minutes. In this manner, on the surface of the low temperature buffer layer, an underlayer composed of GaN having a thickness of 3 μm is formed. These low temperature buffer layer and underlayer form the undoped GaN layer 13.

As the substrate 11, a GaN substrate may be used. Also in this case, as is case with the sapphire substrate, after conducting surface cleaning in the MOCVD device, the furnace temperature of the MOCVD device is set at 1050° C., and while nitrogen gas at a flow rate of 20 slm and hydrogen gas at a flow rate of 15 slm are flowed as a carrier gas in the treatment furnace, TMG at a flow rate of 100 μmol/min and ammonia at a flow rate of 250000 μmol/min are fed as a source gas into the treatment furnace for 60 minutes. In this manner, on the surface of the GaN substrate, the undoped GaN layer 13 having a thickness of 3 μm is formed.

(Step S2)

Next, on the upper face of the undoped GaN layer 13, the n-type semiconductor layer 15 is formed. One example of a specific method is as follows.

Subsequently, in the condition that the furnace temperature is kept at 1150° C., the furnace pressure of the MOCVD device is set at 30 kPa. Then, while nitrogen gas at a flow rate of 20 slm and hydrogen gas at a flow rate of 15 slm are flowed as a carrier gas in the treatment furnace, TMG at a flow rate of 94 μmol/min, trimethylaluminum (TMA) at a flow rate of 6 μmol/min, ammonia at a flow rate of 250000 μmol/min, and tetraethylsilane at a flow rate of 0.025 μmol/min for doping an n-type impurity are fed as a source gas into the treatment furnace for 60 minutes. In this manner, on the upper face of the undoped GaN layer 13, the n-type semiconductor layer 15 composed of AlGaN with an Al composition of 5%, and having a Si concentration of 3×10¹⁹/cm³ and a thickness of 2 μm is formed.

While the case of employing Si as the n-type impurity contained in the n-type semiconductor layer 15 is described in the above embodiment, Ge, S, Se, Sn, Te and the like may be used as other n-type impurities.

(Step S3)

Next, on the upper face of the n-type semiconductor layer 15, the superlattice layer 20 composed of GaN/InGaN is formed. One example of a specific method is as follows.

The furnace pressure of the MOCVD device is set at 100 kPa, and the furnace temperature is set at 820° C. Then, the step of feeding TMG at a flow rate of 15.2 μmol/min, trimethylindium (TMI) at a flow rate of 27.2 μmol/min and ammonia at a flow rate of 375000 μmol/min as a source gas into the treatment furnace for 54 seconds while flowing nitrogen gas at a flow rate of 15 slm and hydrogen gas at a flow rate of 1 slm as a carrier gas in the treatment furnace is conducted. Then, the step of feeding TMG at a flow rate of 15.2 μmol/min and ammonia at a flow rate of 375000 μmol/min into the treatment furnace for 54 seconds is conducted. Then, by repeating these two steps, the superlattice layer 20, in which the InGaN layer 23 having a thickness of 2.5 nm and an In composition of 7%, and the GaN layer 21 having a thickness of 2.5 nm are laminated ten cycles, is formed on the upper face of the n-type semiconductor layer 15.

As described above, the superlattice layer 20 can be formed as a laminate of InGaN having a low In composition and InGaN having a high In composition. In this case, as step S3, the step of feeding TMG at a flow rate of 15.2 μmol/min, TMI at a flow rate of 27.2 μmol/min and ammonia at a flow rate of 375000 μmol/min into the treatment furnace for 54 seconds and the step of feeding TMG at a flow rate of 15.2 μmol/min, TMI at a flow rate of 1 μmol/min and ammonia at a flow rate of 375000 μmol/min into the treatment furnace for 54 seconds as a source gas while flowing nitrogen gas at a flow rate of 15 slm and hydrogen gas at a flow rate of 1 slm are conducted. Then, by repeating these two steps, the superlattice layer 20, in which the InGaN layer 23 having a thickness of 2.5 nm and an In composition of 7%, and the InGaN layer 21 having a thickness of 2.5 nm and an In composition of less than or equal to 1% are laminated ten cycles, is formed on the upper face of the n-type semiconductor layer 15.

(Step S4)

Next, on the upper face of the superlattice layer 20, the first layer 31 composed of In₁Ga_{1-X1}N (0≦X1≦0.01), the second layer 32 composed of In_{X2}Ga_{1-X2}N (0.2<X2<1), and the third layer 33 composed of Al_{Y1}Ga_{1-Y1}N (0<Y1<1) are formed.

Step S4 is made up of performing step S4a of forming the second layer 32, step S4b of forming the third layer 33, and step S4c of forming the first layer 31 multiple times. Throughout step S4, the furnace pressure of the MOCVD device is kept at 100 kPa, and the furnace temperature is kept at 700° C. to 830° C., and nitrogen gas at a flow rate of 15 slm, hydrogen gas at a flow rate of 1 slm, and ammonia at a flow rate of 375000 μmol/min are continuously fed into the treatment furnace.

(Step S4a)

In the condition that hydrogen gas, nitrogen gas, and ammonia are continuously fed at the flow rates as described above at a furnace temperature of 700° C., TMI at a flow rate of 27.2 μmol/min and TMG at a flow rate of 15.2 μmol/min are fed for 54 seconds. In this manner, the second layer 32 composed of undoped InGaN having an In composition of 28% and having a film thickness of 2.6 nm is formed.

(Step S4b)

Subsequently, in the condition that hydrogen gas, nitrogen gas, and ammonia are continuously fed at the flow rates as described above at a furnace temperature of 700° C., TMG at a flow rate of 15.2 μmol/min and TMA at a flow rate of 17.3 μmol/min are fed continuously for 30 seconds. In this manner, the third layer 33 composed of undoped AlGaN having an Al composition of 45% and having a film thickness of 1.5 nm is formed.

(Step S4c)

Subsequently, in the condition that hydrogen gas, nitrogen gas, and ammonia are continuously fed at the flow rates as described above at a furnace temperature of 700° C., TMG at a flow rate of 15.2 μmol/min is fed continuously for 60 seconds to form a GaN layer having a film thickness of 3 nm. Next, the furnace temperature is elevated to 830° C. In the condition that the temperature is kept at this elevated temperature, TMG is continuously fed for 340 seconds at the same gas flow rate to form a GaN layer having a film thickness of 17 nm. As a result, a GaN layer having a film thickness of 20 nm as the first layer 31 is formed.

In the case of forming the first layer 31 of InGaN having a low In composition, the following method is employed in place of the above method. Specifically, in the condition that hydrogen gas, nitrogen gas, and ammonia are continuously fed at the same flow rate as in step S4b, TMG at a flow rate of 1 μmol/min and at a flow rate of 15.2 μmol/min is fed for 400 seconds. In this manner, the first layer 31 formed of undoped InGaN having an In composition of less than or equal to 1% and having a film thickness of 20 nm is formed.

By executing the above steps S4a to S4c five times, the active layer 30 in which the first layer 31, the second layer 32, and the third layer 33 are laminated in five cycles is formed.

In the step of growing InGaN, it is preferred that the growth rate is about 3 nm/min from the view point of controlling droplets as much as possible, and progressing the migration.

(Step S5)

On the upper face of the active layer 30, the undoped GaN layer 41 is formed in a film thickness of, for example, 20 nm. Regarding the undoped GaN layer 41, in the case where the first layer 31 of the active layer 30 is composed of GaN, by ending step S4 with step S4c executed lastly in forming the active layer 30 in step S4, the GaN layer formed in step S4c can be rendered the undoped GaN layer 41. In the case of forming the first layer 31 of InGaN having a low In composition, by ending step S4 with step S4c executed lastly in the condition that feeding of TMI is stopped, the GaN layer formed in step S4c can be rendered the undoped GaN layer 41.

(Step S6)

On the upper face of the undoped GaN layer 41, the p-type semiconductor layer 43 is formed. One example of a specific method is as follows.

The furnace pressure of the MOCVD device is kept at 100 kPa, and the furnace temperature is elevated to 930° C. while nitrogen gas at a flow rate of 15 slm and hydrogen gas at a flow rate of 25 slm are flowed in the treatment furnace as a carrier gas. Thereafter, TMG at a flow rate of 100 μmol/min and ammonia at a flow rate of 250000 μmol/min as a source gas, and bis(cyclopentadienyl)magnesium (Cp₂Mg) at a flow rate of 0.1 μmol/min for doping a p-type impurity are fed into the treatment furnace for 360 seconds. In this manner, on the upper face of the undoped GaN layer 41, the p-type semiconductor layer 43 composed of GaN having a thickness of 120 nm is formed. The p-type impurity (Mg) concentration of the p-type semiconductor layer 43 is about 3×10¹⁹/cm³.

Further, subsequently, a contact layer composed of a high concentration p-type GaN layer having a thickness of 5 nm may be formed by feeding the source gas for 20 seconds after changing the flow rate of Cp₂Mg to 0.3 μmol/min. In this case, the contact layer is involved in the p-type semiconductor layer 43. The p-type impurity (Mg) concentration of the contact layer is about 1×10²⁰/cm³.

While the case of using Mg as a p-type impurity contained in the p-type semiconductor layer 43 is described in the above embodiment, Be, Zn, C and the like may be used besides Mg.

(Subsequent Steps)

The subsequent process is as follows.

In the case of the semiconductor light-emitting element 1 having a so-called “horizontal structure,” part of the upper face of the n-type semiconductor layer 15 is exposed by ICP etching, and above the exposed n-type semiconductor layer 15, an n-side electrode is formed, and above the p-type semiconductor layer 43, a p-side electrode is formed. Then, elements are separated by, for example, a laser dicing device, and wire bonding is conducted on the electrode. Here, the “horizontal structure” refers to a structure in which the n-side electrode formed above the n-type semiconductor layer 15, and the p-side electrode formed above the p-type semiconductor layer 43 are formed in the same direction with respect to the substrate.

On the other hand, in the case of the semiconductor light-emitting element 1 having a so-called “vertical structure,” above the p-type semiconductor layer 43, a metal electrode which is to be a p-side electrode (repeller), a solder diffusion layer, and a solder layer are formed. Then, after bonding a support substrate formed of a conductor or a semiconductor (for example, a CuW substrate) via a solder layer, the resultant object is turned upside down and the substrate 11 is peeled off by a method of laser radiation or the like. Then, an n-side electrode is formed above the n-type semiconductor layer 15. Then, separation of the element and wire bonding are conducted in the same manner as in the horizontal structure. Here, the “vertical structure” refers to a structure in which the n-side electrode and the p-side electrode are formed in the opposite directions with the substrate intervened therebetween.

### Second Embodiment

A second embodiment of the semiconductor light-emitting element of the present invention will be described. Parts common to those in the first embodiment are indicated as such, and the description thereof will be omitted.

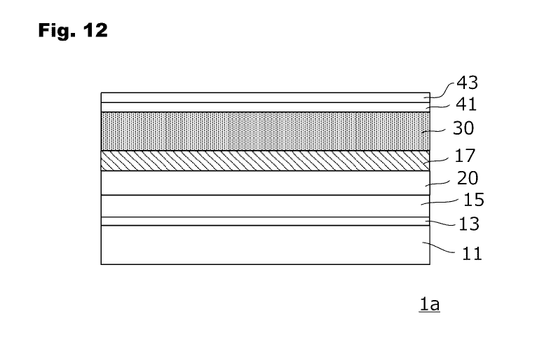

FIG. 12 is a section view schematically showing a structure of the second embodiment of the semiconductor light-emitting element. A semiconductor light-emitting element la shown in FIG. 12 is different from the semiconductor light-emitting element 1 shown in FIG. 1 only in that a hole barrier layer 17 is further provided between the superlattice layer 20 and the active layer 30, and is common in the remaining points.

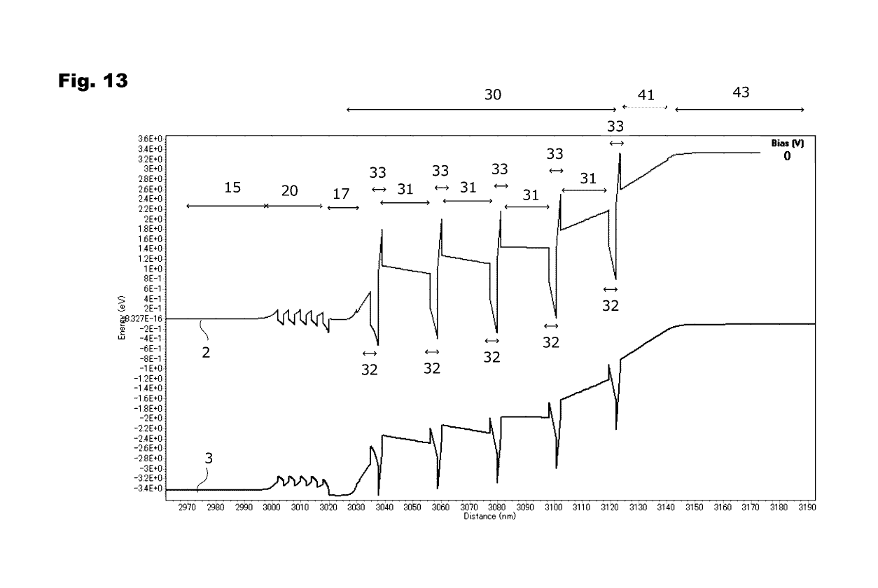

The hole barrier layer 17 is composed of a nitride semiconductor layer doped with Si. The function of the hole barrier layer 17 will be described by comparing the energy band chart of the semiconductor light-emitting element 1a shown in FIG. 13 with the energy band chart of the semiconductor light-emitting element 1 shown in FIG. 8B.

According to the energy band chart of the semiconductor light-emitting element 1 shown in FIG. 8B, the band has inclination between the superlattice layer 20 and the active layer 30. In contrast to this, according to the energy band chart of the semiconductor light-emitting element la shown in FIG. 13, it can be found that the energy gap expands between the superlattice layer 20 and the active layer 30 due to the existence of the hole barrier layer 17, and the band chart between the superlattice layer 20 and the active layer 30 is flattened.

As is already described in the section of “MEANS FOR SOLVING THE PROBLEMS,” in the vicinity of the joint face between the third layer 33 and the first layer 31, a groove is formed in the band chart of the valence band of the active layer, and holes are two-dimensionally accumulated in the groove (two-dimensional hole gas). Since these holes have high mobility in the two-dimensional direction, there is a possibility of occurrence of an overflow phenomenon in which holes injected into the active layer 30 from the side of the p-type semiconductor layer 43 go over the active layer 30 without recombining with electrons.

When the overflow phenomenon of holes occurs, the holes are accumulated in the well region formed by InGaN of the superlattice layer 20 of GaN/InGaN formed between the active layer and the n-type semiconductor layer. As a result, an electron injected from the n-type semiconductor layer 15 recombines with a hole in the superlattice layer 20, and the light with an undesired wavelength is generated. This is not desired because the light showing a peak wavelength different from the peak wavelength of the light generated in the active layer is generated.

According to the energy band chart shown in FIG. 13, the band chart is pushed up by the hole barrier layer 17, and thus flowing of the holes overflowing the active layer 30 into the superlattice layer 20 is controlled. As a result, generation of undesired light is controlled in the superlattice layer 20 of GaN/InGaN.

The higher the concentration of Si for doping the nitride semiconductor layer formed as the hole barrier layer 17 is, the more the band chart can be flattened. However, since surface roughing occurs in the nitride semiconductor layer as the Si concentration exceeds 5×10¹⁹/cm³, the Si concentration is preferably greater than or equal to 5×10¹⁸/cm³ and less than or equal to 5×10¹⁹/cm³. When the Si concentration is lower than 5×10¹⁸/cm³, the effect of controlling overflow of holes is low.

Also as described above with reference to FIG. 3A and FIG. 3B, in order to realize the nitride semiconductor layer showing a very high Si concentration of greater than or equal to 1×10¹⁹/cm³ with a good surface condition, it is preferred to use AlGaN as the hole barrier layer 17. GaN may be used when the Si concentration falls within the range of less than 1×10¹⁹/cm³.

In producing the semiconductor light-emitting element la of the present embodiment, step S3A as described below may be further added between step S3 and step S4 for forming the hole barrier layer 17.

(Step S3A)

After executing steps S1 to S3 in the same manner as in the first embodiment, in the condition that the furnace temperature is still set at 820° C., the step of feeding TMG at a flow rate of 15.2 μmol/min, TMA at a flow rate of 1 μmol/min, tetraethylsilane at a flow rate of 0.002 μmol/min and ammonia at a flow rate of 375000 μmol/min into the treatment furnace for 400 seconds is conducted. In this manner, an AlGaN layer as the hole barrier layer 17 having a Si concentration of 3×10¹⁹/cm³, a thickness of 20 nm, and an Al composition of 6% is formed on the upper face of the superlattice layer 20.

Since the production process following step S4 is similar to that in the first embodiment, the description thereof is omitted.

### Third Embodiment

A third embodiment of the semiconductor light-emitting element of the present invention will be described. The third embodiment is common to the first embodiment or the second embodiment except for the configuration of the active layer 30.

In the above embodiment, the third layer 33 of AlGaN is provided over the whole cycles of the active layer 30. However, the third layer 33 is not required to be necessarily provided in every cycle. Particularly, it is also preferred that the third layer 33 is provided only in a position near the p-type semiconductor layer 43, and the third layer 33 is not provided in a position near the n-type semiconductor layer 15 in the active layer 30. In this case, in the active layer 30, the first layer 31, the second layer 32 and the third layer 33 are cyclically formed in a position near the p-type semiconductor layer 43, and the first layer 31 and the second layer 32 are cyclically formed in a position near the n-type semiconductor layer 15.

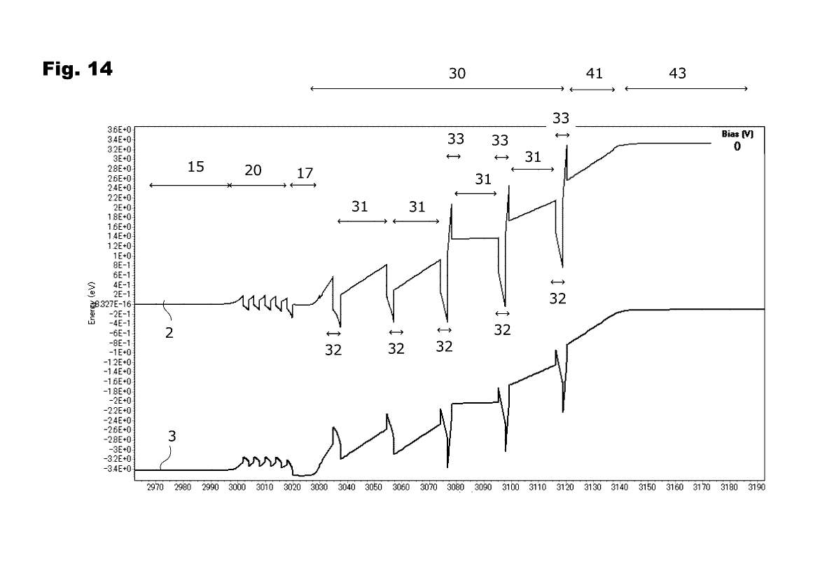

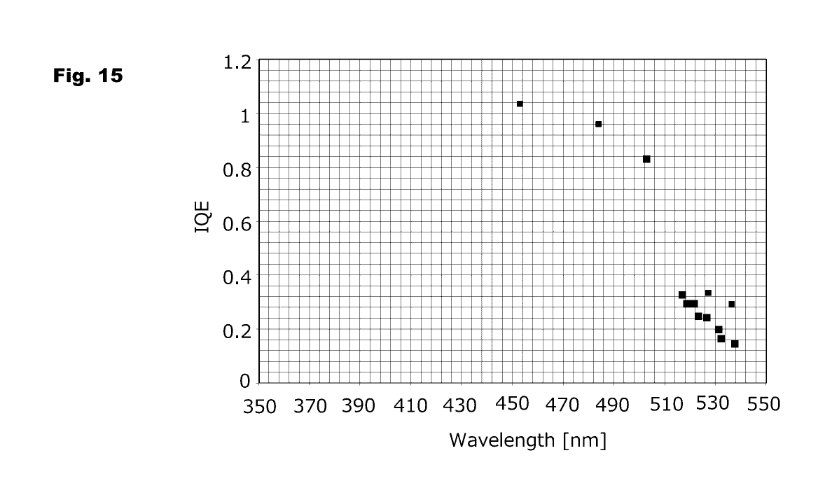

FIG. 14 is an energy band chart when the third layer 33 is provided only in a position near the p-type semiconductor layer 43 and the third layer 33 is not provided in a position near the n-type semiconductor layer 15 in the configuration of the semiconductor light-emitting element la of the second embodiment. Similarly to the semiconductor light-emitting element 1 for which the energy band chart is shown in FIG. 13, the active layer 30 has a structure composed of five cycles. However, for the two cycles in a position near the n-type semiconductor layer 15, the active layer 30 has a cyclic structure of the first layer 31 and the second layer 32. Regarding the three cycles in a position near the p-type semiconductor layer 43, similarly to those shown in FIG. 13, the active layer 30 has a cyclic structure of the first layer 31, the second layer 32, and the third layer 33.

As described above, since the third layer 33 composed of AlGaN has a larger energy band gap than the first layer 31 composed of GaN (or InGaN having a low In composition) does, it forms an energy barrier against electrons migrating to the side of the p-type semiconductor layer 43. However, in the configuration of FIG. 8B, an energy barrier by the third layer 33 is also formed in a position near the n-type semiconductor layer 15. As a result, migration of electrons supplied from the n-type semiconductor layer 15 is interfered with by the energy barrier formed in a position near the n-type semiconductor layer 15, and thus the probability that the electrons are taken into the well region formed by the second layer 32 can decrease.

In contrast to this, in the configuration of FIG. 14, since the third layer 33 does not exist in the region formed on the side of the n-type semiconductor layer 15 in the active layer 30, a high energy barrier that interferes with migration of electrons does not exist. Therefore, when a voltage is applied to the semiconductor light-emitting element 1, electrons flow into the active layer 30 to the position where the third layer 33 is formed with high probability. Then, as a result of interference with migration of part of electrons by the energy barrier of the third layer 33, electrons can be taken into the well region formed by the second layer 32 with high probability. As a result, it is possible to recombine an electron with a hole with high probability in the well region. That is, by employing the element configuration showing the energy band chart in FIG. 14, it is possible to improve the light emission efficiency in comparison with the element configuration showing the energy band chart in FIG. 13.

In producing the semiconductor light-emitting element la having this configuration, step S4a and step S4c should be repeatedly executed in the early stage of step S4, and then step S4a, step S4b, and step S4c should be repeatedly executed. The remaining process is similar to the method as described above.

While in the above description, the case of the semiconductor light-emitting element 1a of the second embodiment is taken as an example, it is also possible to employ a configuration in which the third layer 33 is provided only in a position near the p-type semiconductor layer 43, and the third layer 33 is not provided in a position near the n-type semiconductor layer 15 in the semiconductor light-emitting element 1 of the first embodiment.

### DESCRIPTION OF REFERENCE SIGNS

1, 1a: Semiconductor light-emitting element

2: Conduction band

3: Valence band

11: Substrate

13: Undoped GaN layer

15: n-type semiconductor layer

17: Hole barrier layer

20: Superlattice layer

21: GaN layer constituting superlattice layer

23: InGaN layer constituting superlattice layer

30: Active layer

31: First layer constituting active layer

32: Second layer constituting active layer

33: Third layer constituting active layer

41: Undoped GaN layer

43: p-type semiconductor layer

50: Active layer possessed by semiconductor light-emitting element of Comparative Example

51: GaN layer constituting active layer possessed by semiconductor light-emitting element of Comparative Example

52: InGaN layer constituting active layer possessed by semiconductor light-emitting element of Comparative Example

55: n-type semiconductor layer possessed by semiconductor light-emitting element of Comparative Example

57: Electron block layer possessed by semiconductor light-emitting element of Comparative Example

60: Semiconductor light-emitting element of Comparative Example

62: Conduction band

63: Valence band

71: Defect derived from undoped GaN layer

72: Defect derived from active layer

1. A semiconductor light-emitting element having a peak emission wavelength of greater than or equal to 530 nm, comprising:
an n-type semiconductor layer;
an active layer formed above the superlattice layer n type semiconductor layer; and
a p-type semiconductor layer formed above the active layer, wherein
in the active layer, a first layer composed of In₁Ga_{1-X1}N (0≦X1≦0.01), a second layer composed of In_{X2}Ga_{1-X2}N (0.2<X2<1), and a third layer composed of Al_{Y1}Ga_{1-Y1}N (0<Y1<1) are laminated, and at least the first layer and the second layer are formed cyclically;
the second layer is composed of In_{X2}Ga_{1-X2}N (0.28≦X2≦0.33) having a film thickness of greater than or equal to 2.4 nm and less than or equal to 2.8 nm; and
letting a film thickness of the first layer be T1, a film thickness of the second layer be T2, and a film thickness of the third layer be T3, relations of 5T2 <T1 <10T2 and T3 <T2 are satisfied.

2. (canceled)

3. (canceled)

4. The semiconductor light-emitting element according to claim 1, wherein in the active layer, the first layer, the second layer and the third layer are cyclically formed in a position near the p-type semiconductor layer, and the first layer and the second layer are cyclically formed in a position near the n-type semiconductor layer.

5. (canceled)

6. (canceled)

7. The semiconductor light-emitting element according to claim 1, wherein the third layer is composed of Al_{Y1}Ga_{1-Y1}N (0.2≦Y1 ≦0.5).

8. The semiconductor light-emitting element according to claim 1, wherein the n-type semiconductor layer is composed of AlGaN having a Si concentration of greater than or equal to 3×10¹⁹/cm³.

9. (canceled)

10. The semiconductor light-emitting element according to claim 1, further comprising a superlattice layer formed above the n-type semiconductor layer and composed of a laminate of a plurality of nitride semiconductors having different band gaps, wherein the active layer is formed above the superlattice layer.

11. The semiconductor light-emitting element according to claim 10, further comprising a hole barrier layer composed of a nitride semiconductor layer between the superlattice layer and the active layer.

12. The semiconductor light-emitting element according to claim 11, wherein the hole barrier layer is composed of a nitride semiconductor layer having a Si concentration of greater than or equal to 5×10¹⁸/cm³ and less than or equal to 5×10¹⁹/cm³.

13. The semiconductor light-emitting element according to claim 10, wherein
the superlattice layer is composed of a laminate of a fourth layer and a fifth layer,
the fifth layer is an InGaN layer, and
the fourth layer is a GaN layer, or an InGaN layer having a lower In composition than the fifth layer does.
